(19) United States
(12) Patent Application Publication
(10) Pub. No.: US 2025/0102676 A1
(43) Pub. Date: Mar. 27, 2025

(54) LIDAR WITH MICROLENS ARRAY AND INTEGRATED PHOTONIC SWITCH ARRAY

(71) Applicant: nEye Systems, Inc., Emeryville, CA (US)

(72) Inventors: Tae Joon SEOK, El Cerrito, CA (US); Xiaosheng ZHANG, Davis, CA (US); Kyungmok KWON, El Cerrito, CA (US); Ming Chiang A. WU, Piedmont, CA (US)

(21) Appl. No.: 18/907,413

(22) Filed: Oct. 4, 2024

Related U.S. Application Data
(63) Continuation of application No. 17/748,759, filed on May 19, 2022, now Pat. No. 12,140,676.
(60) Provisional application No. 63/190,672, filed on May 19, 2021.

(51) Int. Cl. G01S 17/89; G01S 7/481; G01S 7/4863; H01L 31/107

(52) U.S. Cl. CPC G01S 17/89; G01S 7/481; G01S 7/4863; H10F 30/225

(57) ABSTRACT

The present disclosure is directed to imaging LiDARs with optical antennas fed by optical waveguides. The optical antennas can be activated through an optical switch network that connects the optical antennas to a laser source to a receiver. A microlens array is positioned between a lens of the LiDAR system and the optical antennas, the microlens array being positioned so as to transform an emission angle from a corresponding optical antenna to match a chief ray angle of the lens. Methods of use and fabrication are also provided.

### PRIORITY CLAIM

This patent application is a continuation of U.S. patent application Ser. No. 17/748,759, titled “LIDAR WITH MICROLENS ARRAY AND INTEGRATED PHOTONIC SWITCH ARRAY” and filed on May 19, 2022, which claims the benefit of priority to U.S. Provisional Patent Application No. 63/190,672, titled “LIDAR WITH MICROLENS ARRAY AND INTEGRATED PHOTONIC SWITCH ARRAY” and filed on May 19, 2021. The content of each of these applications is herein incorporated by reference in its entirety.

### INCORPORATION BY REFERENCE

All publications and patent applications mentioned in this specification are herein incorporated by reference to the same extent as if each individual publication or patent application was specifically and individually indicated to be incorporated by reference.

### FIELD

The present disclosure details novel LiDAR systems and methods. More specifically, this disclosure is directed to imaging LiDARs with microlens arrays to match the emission angles of optical antennas and the receiving angles of the imaging lens.

### BACKGROUND

Light detection and ranging (LiDAR) is widely used in autonomous vehicles and portable devices such as smartphones and tablets. Solid state LiDARs are particularly attractive because they are conducive to miniaturization and mass production. US Patent Pub. No. 2021/0116778 teaches a beamsteering system consisting of a programmable array of vertical couplers (also called optical antennas) located at the focal plane of an imaging lens. Optical signal can be delivered to any selected optical antenna through a programmable optical network consisting of MEMS (micro-electro-mechanical system)-actuated waveguide switches. Compared with conventional thermo-optic or electro-optic switches, the MEMS switches offer lower insertion loss, lower crosstalk, broadband operation, digital actuation, and lower power consumption. High density arrays of programmable optical antennas can be integrated on single chips for high resolution imaging LiDARs, thanks to their small footprint.

Previous disclosure tailored the emission angle of individual optical antennas to match the acceptance angle of the imaging lens. The emission angles of the optical antennas in some embodiments are sensitive to the fabrication process. They may also affect the reflections back to the detectors, which are not desirable. The present disclosure describes the use of microlens arrays to match the emission angles of the antennas and the acceptance angles of the imaging lens.

### BRIEF DESCRIPTION OF THE DRAWINGS

The novel features of the invention are set forth with particularity in the claims that follow. A better understanding of the features and advantages of the present invention will be obtained by reference to the following detailed description that sets forth illustrative embodiments, in which the principles of the invention are utilized, and the accompanying drawings of which:

FIG. 1A is one example of imaging-based LiDAR.

FIG. 1B shows a programmable optical switch network can connect a selected Tx antenna to the laser and a Rx antenna in the same pair to the receiver.

FIG. 2 is the cross-sectional view of the imaging-based LiDAR with an ideal lens. Optical antenna can emit light in any direction towards the ideal lens with unlimited acceptance angle.

FIG. 3A illustrates the chief ray angle (CRA) of the imaging lens for various positions on the focal plane. In some lenses, the extensions of the CRA lines converge at the center of the exit pupil on the image side.

FIG. 3B illustrates the CRAs of general lenses. In some lenses, particularly lenses with multiple elements, the extensions of the CRA lines do not necessarily intersect at the same point.

FIG. 4 illustrates the use of a microlens array between the lens and the focal plane optical antenna array to match the antenna emission angles and the CRAs of the lens. The microlens array is anti-reflection-coated to minimize reflections.

FIG. 5 shows that the microlens array can match the emission angles with the CRAs of the lens even when the emission angles are not 90 degrees (or perpendicular to the focal plane).

FIGS. 6A-6B show one example layout of the optical antennas and the microlens array. Both are two-dimensional arrays with regular pitches, but the pitch of the microlens array is different from that of the antenna array.

FIG. 7 shows the overlay of the optical antenna array and the microlens array. The offset between the microlens and the antenna is designed to bend the optical beams from the optical antennas to match the CRAs of the lens. The microlens array also works for the received optical beams in a reciprocal way.

FIGS. 8A-8B show one example layout in which the optical antenna array, the microlens array, or both, is aperiodic. The offset between the microlens and the antenna is customized at each antenna (pixel) to match the emission angle of the antenna and the CRA of the lens.

FIG. 9 shows the overlay of the optical antenna array and the aperiodic microlens array.

FIG. 10 is one example in which the microlens array is part of the encapsulation of the focal plane optical antenna array with the gap spacing defined by a spacer.

FIG. 11 illustrates the use of the microlens array in imaging-based pseudo-monostatic LiDAR with separate optical antennas for transmit and receive functions.

FIG. 12 is a specific example of an optical antenna array of optical antennas used in conjunction with a microlens array.

FIG. 13 is a schematic diagram analyzing how a microlens (e.g., from the array of FIG. 12) converts the beam divergence angle.

FIG. 14 shows a calculated beam divergence angle θ1 after the microlens as a function of the microlens radius of curvature R at several different air gap g.

FIG. 15A is a simulated model where the microlens comprises a single-sided microlens.

FIG. 15B is a simulated model where the microlens comprises a double-sided microlens.

### SUMMARY OF THE DISCLOSURE

An imaging LiDAR system is provided, comprising a lens, at least one light emitter, at least one light detector, an antenna array comprising a plurality of optical antennas, a programmable optical switch network configured to provide an optical path from the at least one light emitter to a selected transmit optical antenna and from a selected receiving antenna to the at least one detector, a microlens array comprising a plurality of microlenses corresponding to the plurality of optical antennas of the antenna array, the microlens array being disposed between the plurality of optical antennas and the lens, wherein the microlens array is positioned approximately at a focal plane of the lens and the antenna array is positioned approximately at a focal plane of the microlens array; wherein each microlens of the microlens array is positioned so as to transform an emission angle from a corresponding optical antenna to match a chief ray angle of the lens.

In some embodiments, the microlens array selected from the group consisting of silicon, glass, silicon nitride, polymers, photoresists, plastic, ceramic, dielectric, and other semiconductor materials.

In one embodiment, each microlens is selected from the group consisting of Fresnel lens, meta lens, metasurface lens, an any other artificially synthesized lens.

In some examples, the microlens array further comprises an anti-reflection coatings on one or more surfaces.

In some embodiments, the lens is selected from the group consisting of a single lens, a compound lens, a multiple-element lens, a smartphone lens, and a telephoto lens.

In other examples, the system further comprises a spacer disposed along at least one edge of the antenna array, the spacer being configured to maintain an optimal spacing in which the microlens array is positioned approximately at the focal plane of the lens and the antenna array is positioned approximately at the focal plane of the microlens array.

In one embodiment, the spacer and the microlens array form a sealed cavity.

In another embodiment, the sealed cavity is hermetic.

In some embodiments, the plurality of optical antennas comprise separate transmit and receive optical antennas and separate optical paths connecting to these separate transmit and receive optical antennas.

In one example, the microlens array comprises a single-sided design. In other examples, the microlens array comprises a double-sided design.

In some examples, the microlens array is periodic and the antenna array is periodic. In other examples, the microlens array is not periodic and the antenna array is periodic, or vis versa.

In some examples, the microlens array and the antenna array both have fiducial markers configured to allow for alignment and permanent attachment.

In other embodiments, the plurality of optical antennas have an emission angle of 8° and a beam divergence angle of 30°. In one specific example, the microlens array is configured to convert the beam divergence angle to 22° and the emission chief ray angles (CRA) to a value ranging between 0° ˜37°.

A programmable integrated circuit (PIC) for an imaging LiDAR system is provided, comprising an antenna array comprising a plurality of optical antennas, a programmable optical switch network configured to provide an optical path to a selected transmit optical antenna and from a selected receiving antenna; and a microlens array comprising a plurality of microlenses corresponding to the plurality of optical antennas of the antenna array, wherein the antenna array is positioned approximately at a focal plane of the microlens array, wherein each microlens of the microlens array is positioned so as to transform an emission angle from a corresponding optical antenna to match a chief ray angle of a lens of the imaging LiDAR system.

In some embodiments, the microlens array selected from the group consisting of silicon, glass, silicon nitride, polymers, photoresists, plastic, ceramic, dielectric, and other semiconductor materials.

In other embodiments, each microlens is selected from the group consisting of Fresnel lens, meta lens, metasurface lens, an any other artificially synthesized lens.

In one example, the microlens array further comprises an anti-reflection coatings on one or more surfaces.

In another embodiment, the PIC further comprises a spacer disposed along at least one edge of the antenna array, the spacer being configured to maintain an optimal spacing in which the antenna array is positioned approximately at the focal plane of the microlens array.

In some examples, the spacer and the microlens array form a sealed cavity. In one embodiment, the sealed cavity is hermetic.

In some examples, the plurality of optical antennas comprise separate transmit and receive optical antennas and separate optical paths connecting to these separate transmit and receive optical antennas.

In one example, the microlens array comprises a single-sided design. In other examples, the microlens array comprises a double-sided design.

In some examples, the microlens array is periodic and the antenna array is periodic. In other examples, the microlens array is not periodic and the antenna array is periodic, or vis versa.

In some embodiments, the microlens array and the antenna array both have fiducial markers configured to allow for alignment and permanent attachment.

In one example, the plurality of optical antennas have an emission angle of 8° and a beam divergence angle of 30°. In one specific example, the microlens array is configured to convert the beam divergence angle to 22° and the emission chief ray angles (CRA) to a value ranging between 0°˜37°.

A method of performing LiDAR imaging is provided, comprising the steps of controlling a programmable optical network to provide a first light path from at least one light emitter to a selected transmit optical antenna of an antenna array of the optical network, positioning a microlens array such that the microlens array is positioned approximately at a focal plane of a lens and the antenna array is positioned approximately at a focal plane of the microlens array, the microlens array comprising a plurality of microlenses corresponding to the antenna array, and transforming an emission angle of the selected transmit optical antenna to match a chief ray angle of the lens.

A method of fabricating a programmable integrated circuit (PIC) for an imaging LiDAR system is provided, comprising forming an optical antenna array with a photolithography process, the optical antenna array comprising a plurality of optical antennas, forming a programmable optical switch network with the photolithography process, the programmable optical switch network being configured to provide an optical path to a selected transmit optical antenna and from a selected receiving antenna, and forming a microlens array with a photolithography process, the microlens array comprising a plurality of microlenses corresponding to the plurality of optical antennas of the antenna array, wherein the antenna array is positioned approximately at a focal plane of the microlens array, wherein each microlens of the microlens array is positioned so as to transform an emission angle from a corresponding optical antenna to match a chief ray angle of a lens of the imaging LiDAR system.

In some examples, the optical antenna array, the programmable optical switch network, and the microlens array are formed from a material selected from the group consisting of silicon, glass, silicon nitride, polymers, photoresists, plastic, ceramic, dielectric, and other semiconductor materials.

In some examples, the method further comprises forming a spacer with a photolithography process, the spacer being configured to maintain an optimal spacing in which the antenna array is positioned approximately at the focal plane of the microlens array.

In one example, the spacer and the microlens array form a sealed cavity.

In another example, the sealed cavity is hermetic.

### DETAILED DESCRIPTION

The present disclosure is directed to imaging LiDARs with a microlens array between the imaging lens and the focal plane optical antenna array to match the emission angles from the antenna and the acceptance angles of the imaging lens.

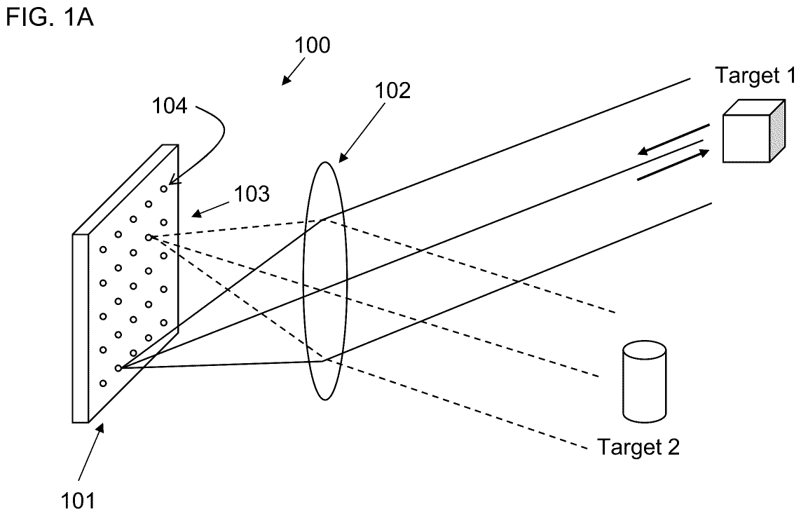

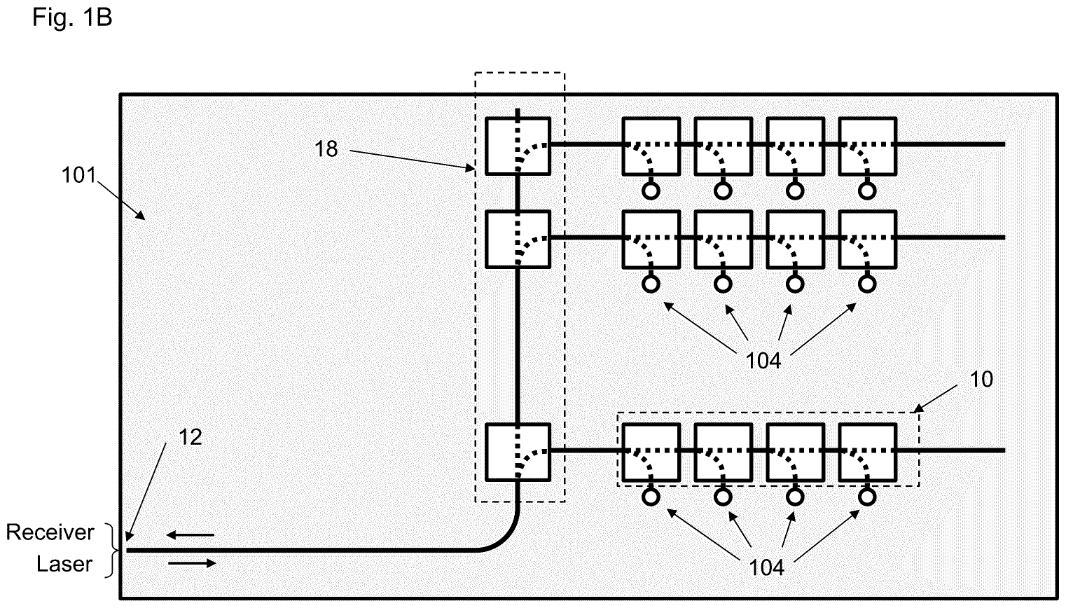

One example schematic of a monostatic imaging LiDAR 100 is shown in FIG. 1A. A photonic integrated circuit (PIC) 101 with a two-dimensional (2D) array 103 of optical antennas is placed at the focal plane of an imaging lens 102. An optical switch network in the PIC selectively activates one or more optical antennas 104 at a time. Each activated optical antenna transmits light to a certain direction (Tx) and the same antenna receives reflected light from target (Rx). This creates a one-to-one mapping between the lateral position of the optical antenna and the far-field angle, as illustrated by the optical beam paths from two separate optical antennas pointing to Target 1 and Target 2. This is referred to herein as monostatic LiDAR, in which the transmitter and the receiver share the same optical antenna. The Tx and the Rx far-field angles are automatically aligned, but the LiDAR receiver is susceptible to residue reflections in the shared optical path and antenna. Residue reflections can comprise unwanted reflections caused by some elements in the optical path from the light source (laser) to the target. These residue reflections can also be delivered to the receiver and they can potentially hinder the detection of the real target signal (especially for weak target signals at longer distances).

Grating couplers are frequently used as optical antennas. Other structures such as prisms, 45-degree (or other angles) mirrors, or end-firing bent waveguides can also be used.

A programmable optical switch network can connect the selected Tx antenna to the laser and the Rx antenna in the same pair to the receiver. Suitable programmable optical switch networks for connecting the monostatic antenna arrays have been described by US Pub. No. US2021/0116778 which is incorporated herein by reference. FIG. 1B illustrates a programmable optical network on a PIC 101 that uses a 1×M switch (row selection switch 18) to select the active row and a 1×N switch (column selection switch 10) to select the optical antenna 104 (FIG. 1B shows a M×N array of optical antennas 104). The programmable optical network can be coupled to a receiver and a laser, as shown. The laser light is modulated, either directly or through a modulator, to generate interrogating light. In pulsed time of flight system, the laser is modulated to produce short (˜ nanosecond) optical pulses, and the receivers are made of avalanche photodiodes (APD) or single photon avalanche diodes (SPAD). In frequency-modulated continuous-wave (FMCW) system, the laser frequency increases or decrease linearly with time. Coherent receivers mix the received light signals with part of the laser light (called local oscillator or LO) in p-i-n photodidoes or APDs to extract the beat frequencies. The p-i-n photodiodes or APDs are often arranged in balanced configuration to extract the difference signals. This system is referred to as FMCW LiDAR or coherent LiDAR. In this example, the 1×M switch comprises M 1×2 switches and the 1×N switch comprises N 1×2 switches. Other possible arrangements are discussed in US Pub. No. US2021/0116778. As mentioned earlier, the Tx and Rx in this embodiment share not only the optical antenna but also the common optical path including waveguides, optical switches, and the input/output coupler 12.

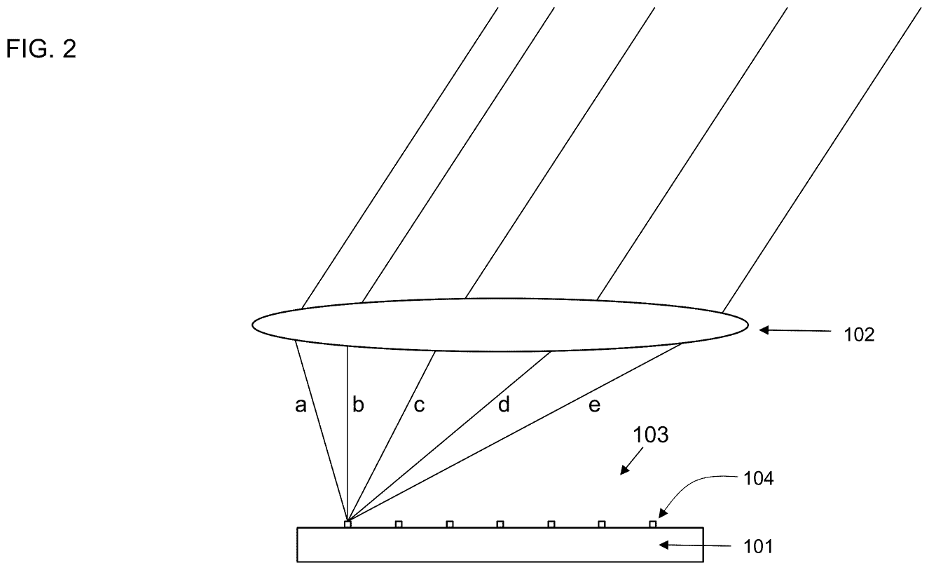

FIG. 2 also shows a PIC 101 with a two-dimensional (2D) array 103 of optical antennas 104 placed at the focal plane of an imaging lens 102. An optical switch network in the PIC selectively activates one or more optical antennas 104 at a time. To achieve maximum optical efficiency, the emission angle of the optical antennas should match the acceptance angles of the lens. If the lens has infinite acceptance angle, the optical antenna can emit at any angles towards the lens and the light will be directed towards the target, as illustrated by emitted beams a-e in FIG. 2.

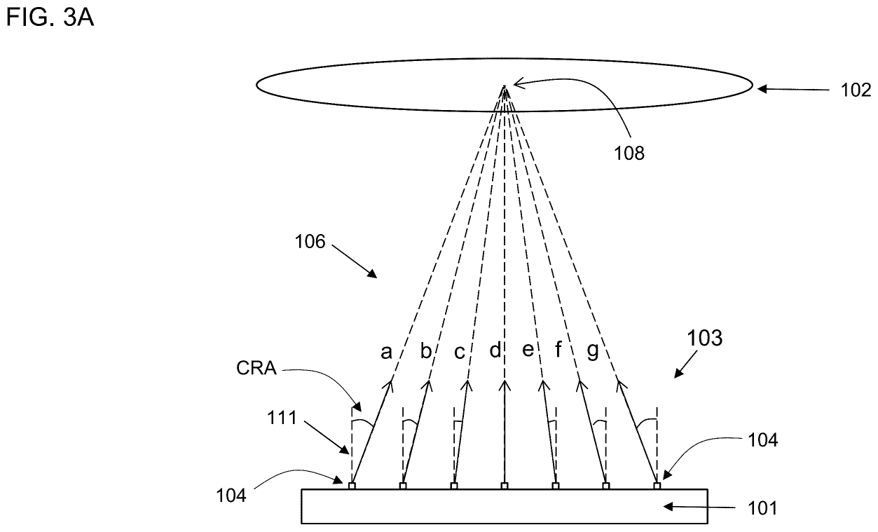

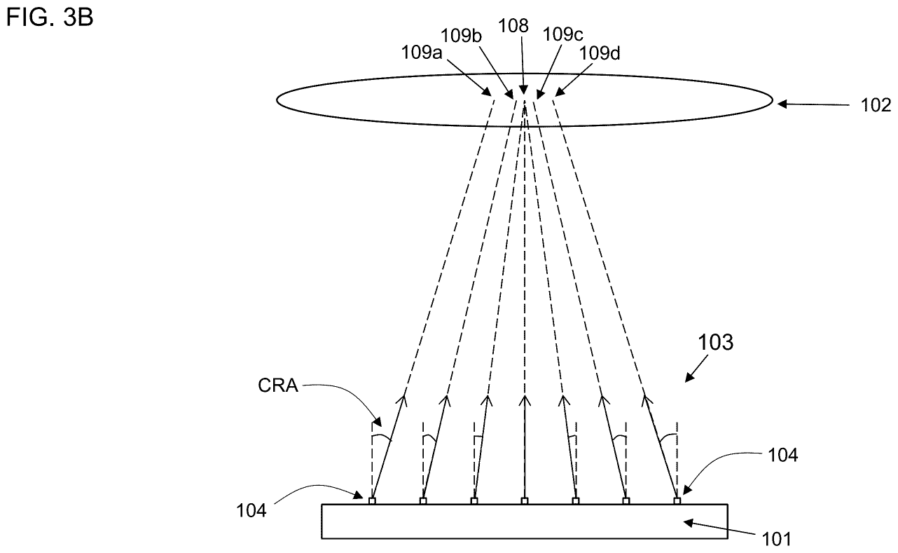

However, referring to FIG. 3A, practical imaging lenses, particularly those with multiple elements, have finite acceptance angles for each pixel in the focal plane. The acceptance angle for the lens 102 of FIG. 3A is dependent on the position of the pixel (e.g., the optical antenna in question). In this example, the acceptance angle comprises a light cone 106 around the chief ray angle (CRA) for each optical antenna 104, which is defined as the angle between the emitted beams (e.g., a, b, c, d, e, f, g, etc.) connecting each pixel/optical antenna to the center 108 of the lens aperture (which is also the exit pupil on the image side) and the normal 111 to the focal plane.

For some lenses, e.g., multi-element lenses, the extensions of the CRAs might not intersect at a single central point. Instead, as illustrated in FIG. 3B, extensions of the CRAs can pass through two or more points in the multi-element lens 102 that may not be at the center 108 of the multi-element lens, as illustrated by points 109a-109d.

In principle, the optical antennas in each pixel can be optimized or configured to emit at an angle approximately equal to the CRA. For example, one can control the pitch and the orientation of a grating coupler, as taught in US Patent Pub. No. 2021/0116778. Similarly, for mirror or prism-based optical antennas, the angle and orientation of the mirror/prism can be adjusted. However, customizing the angles for each pixel poses a challenge to fabrication of mirrors and prisms. Grating couplers with different pitches can be patterned by photolithography, however, the emission angle is sensitive to fabrication variations. The grating diffraction efficiency and the back-reflection are also dependent on grating pitches.

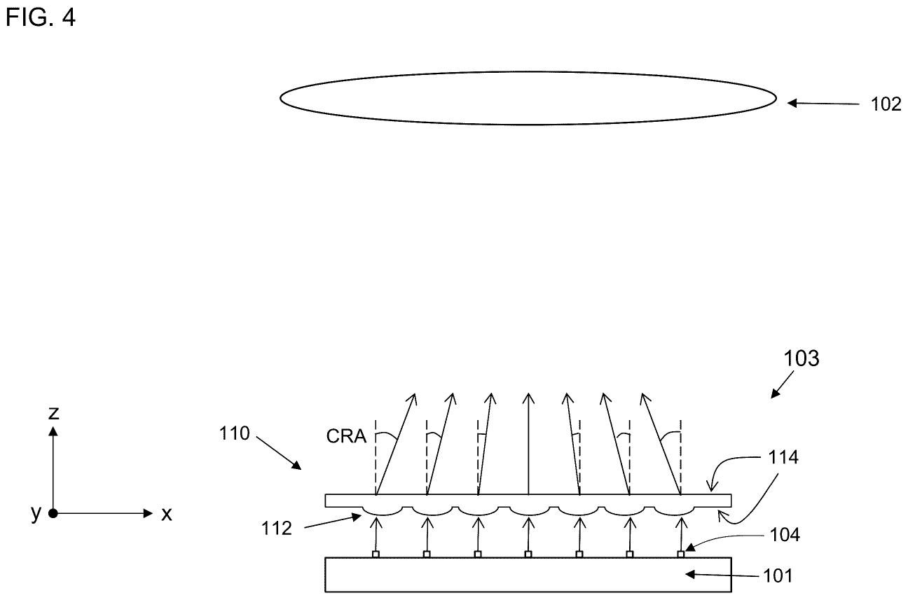

The present disclosure provides a novel microlens array configured to transform the emission angles from one or more optical antennas to match the CRAs of the imaging lens. One example of the embodiment is shown in FIG. 4. In this example, a microlens array 110 comprising a plurality of microlenses 112 is disposed between the imaging lens 102 and the optical antenna array 103. In one example, the microlens array can be formed with a photolithography process. While the microlens array in this example is shown as a single-sided design, it should be understood that this embodiment, or any other microlens embodiment described herein, can also be implemented as a double-sided design. In some embodiments, the microlens array can comprise one or more anti-reflective coating(s) 114 disposed on one or more sides of the array. The distance between the lens 102 and the microlens array 110 can be approximately the focal length of the lens, and the distance between the microlens array 110 and the optical antenna array 103 can be approximately the focal length of the microlens. A microlens 112 can be positioned on top of each optical antenna, but the center of each microlens is offset laterally relative to its corresponding optical antenna 104 to bend the optical beams. The beam angle after passing through each microlens is equal to tan⁻¹ (δr/fₘₗ), where δr is the lateral offset between the centers of each microlens and its corresponding optical antenna in x-y plane (see FIG. 4 for the definition of the coordinates), and fₘₗ is the focal length of the microlens. Since the microlens is fabricated by photolithography, each microlens position can be precisely defined to match the output angle to the CRA of each corresponding individual pixel or optical antenna.

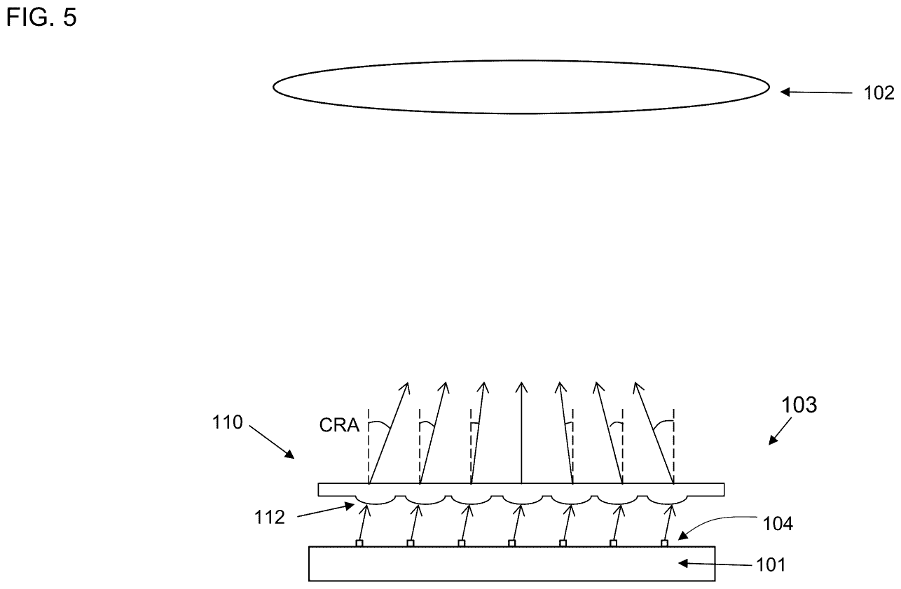

It should be noted that the beam angle after the beam passes through the microlens only depends on the offset between the microlens and the optical antenna. To a large extent, it is independent of the emission angle from the optical antenna, provided the optical beam overlaps with the microlens. This is illustrated in FIG. 5, where it is shown that the microlens array can be configured to match the emission angles with the CRAs of the lens even when the emission angles from the optical antennas are not 90 degrees (or perpendicular to the focal plane). This allows the optical antenna to be optimized for high efficiency without constraint in the emission angle. It also has a large tolerance to fabrication variation of the optical antenna. Even if the emission angle from one or more of the optical antennas differs from the designed angle, the microlens array can still produce an output angle matched to the CRA of the lens.

Though the examples described here use refractive microlens arrays, other microlenses such as Fresnel lenses, meta lenses, metasurface lenses, or other artificially synthesized lenses can be used. The microlens can be made in silicon, silicon dioxide, silicon nitride, polymers, plastics, photoresists, or ceramic, dielectric, semiconductor materials, or composite materials. The microlenses can be made by top-down fabrication, injection molding, reflow, or other methods.

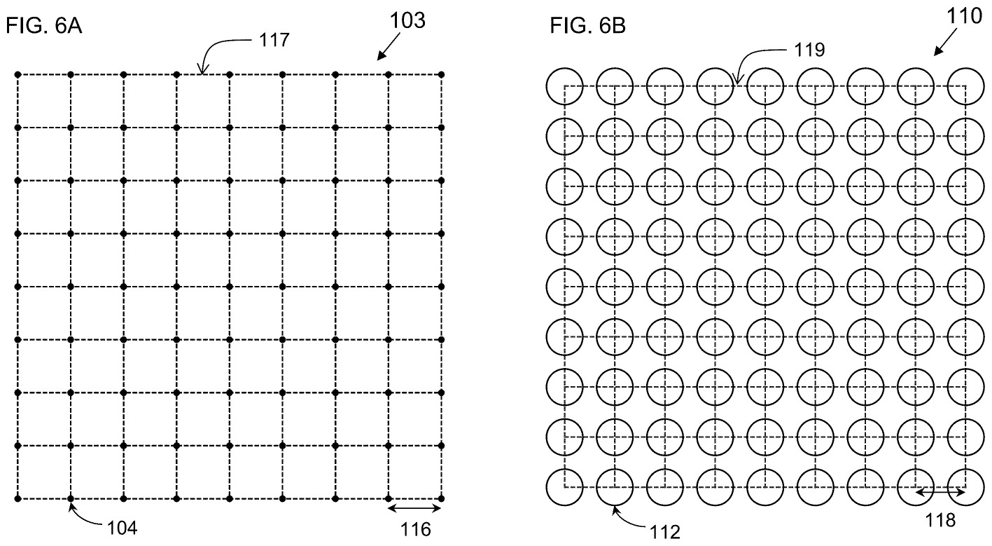

FIGS. 6A-6B show an example layout of the optical antenna array and the microlens array. FIG. 6A illustrates the optical antenna array 103, where each optical antenna 104 is represented by a dot. FIG. 6B illustrates the microlens array 110, and each microlens 112 is represented by a circle. In this embodiment, both the optical antennas and the microlenses are two-dimensional (2D) arrays with regular, but different, pitches. For example, the optical antenna pitch 116 is different than the microlens pitch 118. In some embodiments, the pitch difference can be on the order of tens of nanometers to tens of micrometers. Pitch difference is a fnction of the antenna array design and the lens parameters. Optical antenna grid pattern 117 represents the pitch between adjacent optical antennas, and microlens grid pattern 119 represents the pitch between adjacent microlenses.

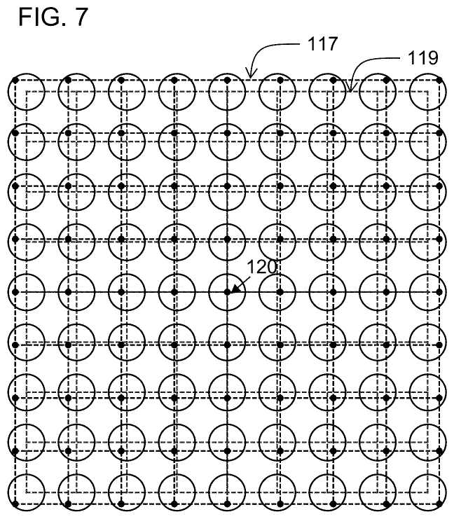

FIG. 7 shows an overlay of the optical antenna and microlens arrays from FIGS. 6A-6B. With a 9×9 grid of optical antennas and microlenses, this example provides a total of 81 optical antennas and 81 corresponding microlenses. At the center 120 of the overlay, the central optical antenna and the center of the microlens are aligned exactly. This leads to vertical output beam. For pixels or optical antennas away from the center of the array, the microlens position is offset towards the center of the array, and the optical antennas are offset outwards from the center of each corresponding microlens. As shown in FIG. 7, the disparity between the optical antenna grid pattern 117 and the microlens grid pattern 119 can be clearly seen. The amount of offset between each respective microlens and optical antenna pair increases with the distance to the center of the array because the CRA usually increases from the center towards the edges of the imaging plane.

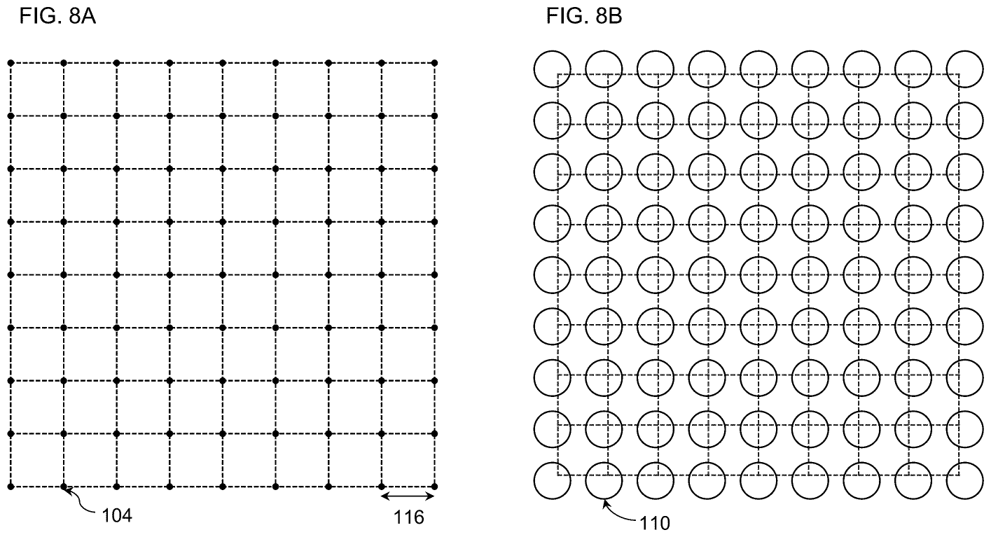

The microlens array does not need to be periodic (e.g., uniform distance between adjacent microlenses). In some examples, the position of each microlens in the array can be optimized for each optical antenna to match the CRA of the lens, as illustrated in FIGS. 8A-8B. Thus, in the example of FIG. 8A, the optical antenna pitch 116 can be uniform or periodic, but in FIG. 8B, the microlens pitch 118 between the various microlenses is not periodic or uniform, but is instead optimized to match the CRA of the lens. In another embodiment, the optical antenna array does not need to be periodic either. The microlens position can still be optimized for aperiodic optical antenna array.

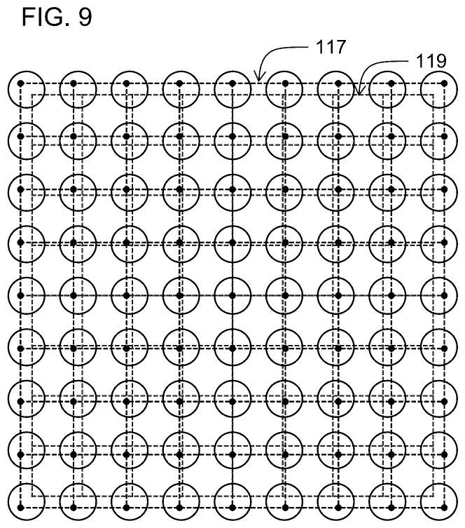

FIG. 9 shows the disparity between the optical antenna grid pattern 117 and the microlens grid pattern 119 when the microlens array is not periodic. While the overlay between the optical antenna grid pattern 117 and the microlens gid pattern 119 is the same as shown in the embodiment of FIG. 7, the amount of offset between each respective microlens and optical antenna pair is less than in the FIG. 7 embodiment due to the microlens array being non-periodic. Specifically, in the FIG. 7 embodiment, especially towards the periphery of the array, the optical antennas are positioned closer to the edges of their corresponding microlenses. However, in this embodiment of FIG. 9, the microlenses are spaced further apart at the periphery of the array, allowing the optical antennas to be more centrally positioned within each of their respective microlenses.

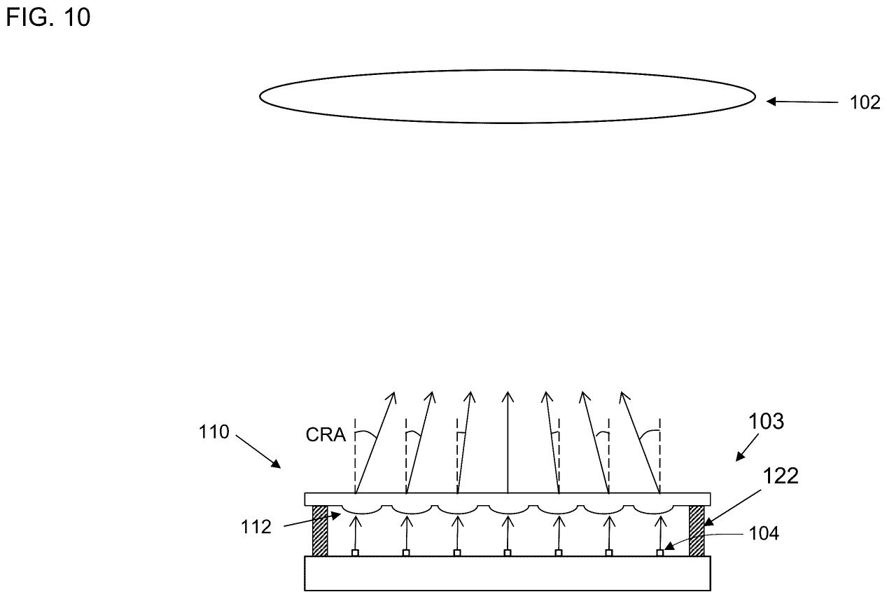

FIG. 10 illustrates a microlens array 110 of microlenses 112 that can be assembled with the optical antenna array 103 of optical antennas 104 at wafer or chip scale. In some embodiments, fiducial markers can be placed on both the microlens array and the optical antenna array. They can be aligned and permanently attached using flip-chip bonding or wafer bonding equipment. A spacer 122 with a height approximately equal to the focal length of the microlens can be fabricated on either the microlens array or the optical antenna array. The spacer can then be configured to precisely define the spacing between the microlens and the optical antenna array 103. The enclosed spacer can additionally provide a hermetic sealing to optical antennas, which can be beneficial if MEMS actuators are used in the optical switch networks. In some embodiments, the spacer can be fabricated from the same material as the microlens (e.g., silicon, silicon dioxide, silicon nitride, polymers, plastics, photoresists, or ceramic, dielectric, semiconductor materials, composite materials, or metal such as gold.)

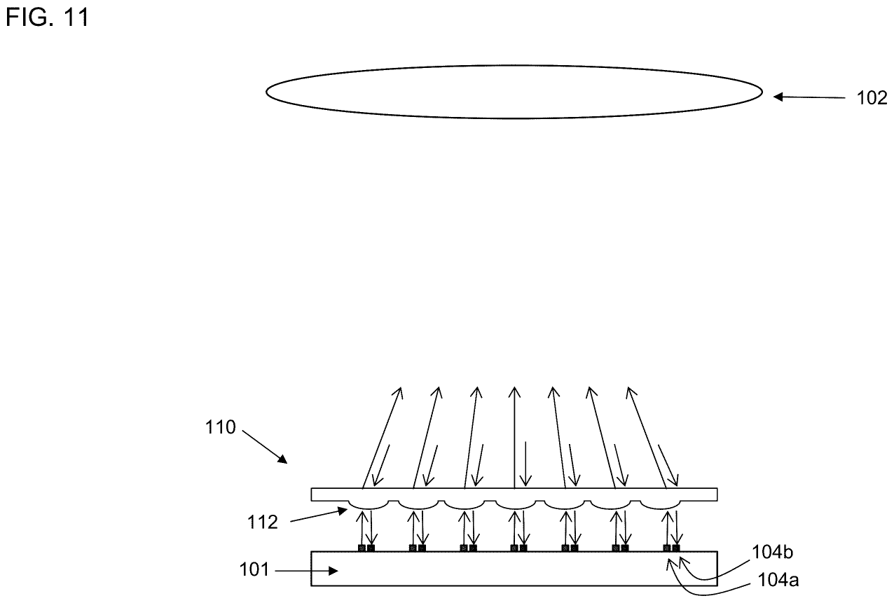

The optical scheme disclosed here is not limited to one optical antenna per pixel. FIG. 11 shows an embodiment for imaging LiDARs with multiple optical antennas per pixel. For example, pseudo-monostatic imaging LiDARs use separate transmit optical antennas 104a and receive optical antennas 104b to reduce crosstalk and residue reflections. Alternatively, receive antennas with orthogonal polarizations can be used to implement polarization-diversity receiver at each pixel. In these examples, the optical antennas can be placed in close proximity (e.g., on the order of hundreds of nanometers to several micrometers) so the corresponding beam angles after the microlens are sufficiently close to the CRA of the pixel.

### Examples

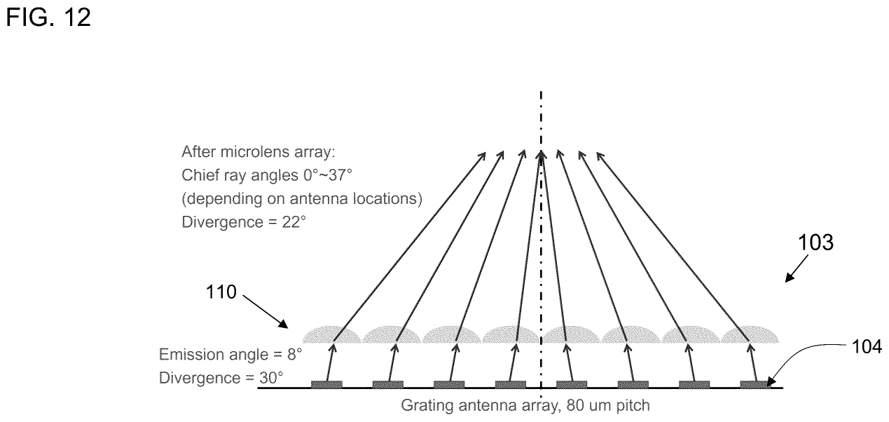

FIG. 12 is a specific example of an optical antenna array 103 of optical antennas 104 used in conjunction with a microlens array 110 as described above. In this example, the array has a pitch of 80 μm, and the optical (grating) antennas have an emission angle of 8° and a divergence angle of 30°. In this embodiment, the microlens array 110 is configured to convert the beam divergence to 22° and the emission chief ray angles (CRA) to a value in the range 0°˜37° depending on the optical antenna locations. This example also assumes that the microlens array is made of silicon (refractive index n=3.48) and has a thickness of 250 μm.

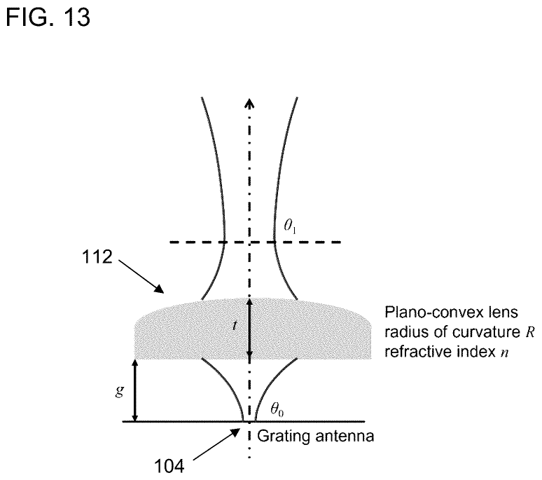

FIG. 13 is a schematic diagram analyzing how a microlens 112 (from the array of FIG. 12) converts the beam divergence angle. In this example, the emitted beam is modeled from the grating antenna as a Gaussian beam with a divergence θ₀=30° and a wavelength of 1550 nm. To simplify the analyses, it is assumed that the Gaussian beam propagates along the optical axis of the microlens. The plano-convex shaped microlens with a top surface radius of curvature R, a thickness of t=250 μm, and a refractive index of n=3.48 is placed above an optical antenna 104 with an air gap g.

The Gaussian beam parameters after the microlens can be approximately calculated using the ABCD matrix method. The ABCD matrix of the system can be computed by multiplying the propagation ABCD matrix in the air gap:

$$[ \begin{matrix}1 & g \\ 0 & 1\end{matrix} ] \qquad Equation 1$$

by the thick lens ABCD matrix:

$$[ \begin{matrix}1 & \frac{t}{n} \\ \frac{n - 1}{- R} & 1 - \frac{t ( n - 1 )}{n R}\end{matrix} ] \qquad Equation 2$$

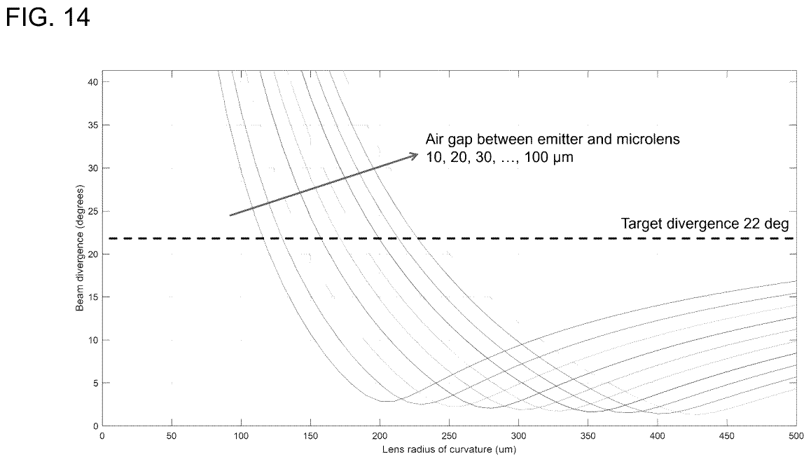

FIG. 14 shows the calculated beam divergence angle θ₁ after the microlens as a function of the microlens radius of curvature R at several different air gap g. The design goal θ₁=22° is indicated by the dashed line. The analytical calculations provide a guideline for selecting the microlens parameters, for example, a radius of curvature of 115 μm and an air gap of 10 μm.

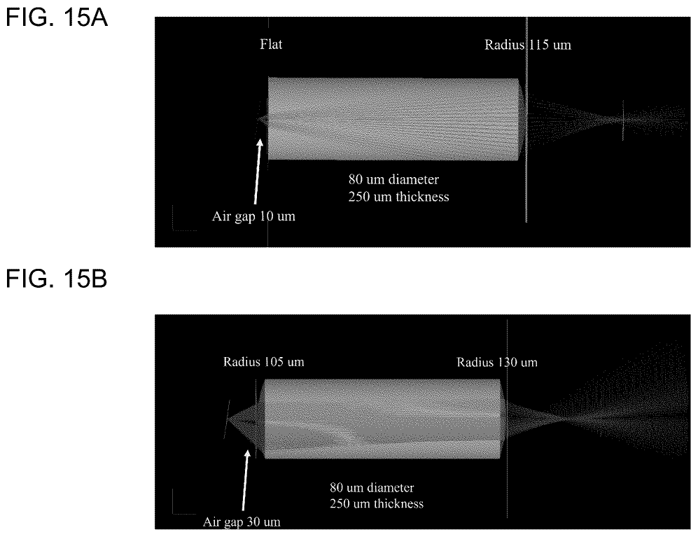

The model in the previous section includes a single-sided (plano-convex) microlens where the lens surface facing the grating antenna is flat. An example design with R=115 μm and g=10 μm is shown in FIG. 15A (simulated by the FRED software). In the example of FIG. 15B, microlens can also be double-sided where both surfaces are curved. In both simulations of FIGS. 15A-15B, the emission angle of the grating antenna is set to 8°.

In the single-sided design shown in FIG. 15A, it can be observed that some of the rays are clipped by the sidewall of the microlens, resulting in a loss of optical efficiency. In contrast, in the double-sided design in FIG. 15B, the first lens surface collimates the light proparating inside the microlens, thus there is no ray clipping loss. However, this collimation relys on a precise gap between the grating antenna and the microlens which requires high fabrication and packaging accuracy.

To achieve the CRA design goal stated above, i.e. change the CRA of the beam after the microlens, each optical antenna needs to be offset from the optical axis of the microlens. The ray clipping loss and CRA after the microlens has been simulated in the FRED software based on the single-sided microlens design shown in FIG. 15A, and the simulation results are listed in Table 1. The simulation results confirm that the beam CRA after microlens can be controlled by offsetting the grating antenna from the microlens optical axis.

TABLE 1
Simulation results of efficiency and CRA after
microlens versus grating antenna offset.

| Offset | Efficiency due to | CRA after microlens |
|---|---|---|
| (μm) | ray clipping loss | (°) |
| −20 | 51.5% | −24.3 |
| −15 | 71.1% | −20.0 |
| −10 | 83.1% | −13.6 |
| −5 | 87.1% | −9.8 |
| 0 | 90.9% | −4.4 |
| 5 | 92.0% | 0.78 |
| 10 | 92.4% | 6.1 |
| 15 | 91.7% | 11.0 |
| 20 | 89.8% | 17.1 |
| 25 | 83.7% | 23.0 |
| 30 | 71.8% | 25.3 |

The systems and methods described herein can be used, for example, to perform range (distance) measurement in multiple directions. Additionally, the systems and methods described herein can be used to perform measurement of 3D point clouds. In some embodiments, the frame rate or speed of 3D point cloud measurement can be increased by turning on multiple pixels at the same time. In some examples, these multiple pixels can be powered by the same laser through an optical splitter. In other embodiments, the multiple pixels can be powered by separate lasers.

As for additional details pertinent to the present invention, materials and manufacturing techniques may be employed as within the level of those with skill in the relevant art. The same may hold true with respect to method-based aspects of the invention in terms of additional acts commonly or logically employed. Also, it is contemplated that any optional feature of the inventive variations described may be set forth and claimed independently, or in combination with any one or more of the features described herein. Likewise, reference to a singular item, includes the possibility that there are plural of the same items present. More specifically, as used herein and in the appended claims, the singular forms “a,” “and,” “said,” and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation. Unless defined otherwise herein, all technical and scientific terms used herein have the same meaning as commonly understood by one of ordinary skill in the art to which this invention belongs. The breadth of the present invention is not to be limited by the subject specification, but rather only by the plain meaning of the claim terms employed.

1. (canceled)

2. An imaging system, comprising:
a lens having an aperture center;
an antenna array comprising a plurality of optical antennas; and
a microlens array comprising a plurality of microlenses corresponding to the plurality of optical antennas of the antenna array,
wherein the microlens array is positioned between the plurality of optical antennas and the lens such that the microlens array is positioned substantially at a focal plane of the lens and the antenna array is positioned substantially at a focal plane of the microlens array, and
wherein centers of at least some of the microlenses of the microlens array are offset relative to corresponding ones of the optical antennas, thereby redirecting light from the corresponding ones of the optical antennas toward the aperture center of the lens.

3. The imaging system of claim 2, wherein the microlens array is formed of a material selected from the group consisting of silicon, glass, silicon nitride, polymers, photoresists, plastic, ceramic, dielectric, and other semiconductor materials.

4. The imaging system of claim 2, wherein each microlens is selected from the group consisting of Fresnel lens, meta lens, metasurface lens, another artificially synthesized lens.

5. The imaging system of claim 2, wherein the lens is selected from the group consisting of a single lens, a compound lens, a multiple-element lens, a smartphone lens, and a telephoto lens.

6. The imaging system of claim 2, further comprising:
a spacer disposed along at least one edge of the antenna array to maintain a spacing such that the microlens array is positioned substantially at the focal plane of the lens and the antenna array is positioned substantially at the focal plane of the microlens array.

7. The imaging system of claim 6, wherein the spacer and the microlens array form a sealed cavity.

8. The imaging system of claim 2, wherein one or both the microlens array and antenna array are periodic.

9. The imaging system of claim 2, wherein one or both the antenna array and microlens array are aperiodic.

10. The imaging system of claim 2, wherein the plurality of optical antennas have an emission angle of 8° and a beam divergence angle of 30°.

11. The imaging system of claim 10, wherein the microlens array is configured to convert the beam divergence angle to 22° and an angle between an emission chief ray and a normal to a focal plane of the lens, to a value ranging between 0°-37°.

12. The system of claim 2, wherein the microlens array is configured to convert an angle between a chief ray and the normal to a focal plane of the lens, to a value ranging between 0°-37°.

13. The imaging system of claim 2, wherein the imaging system comprises an imaging LiDAR system, and wherein the plurality of optical antennas comprise separate transmit and receiving optical antennas configured to transmit and receive light to and from a target via the lens and the microlens array.

14. The imaging system of claim 13, further comprising a programmable optical switch network configured to provide an optical path to a selected transmit optical antenna of the transmit optical antennas and from a selected receiving antenna of the receiving optical antennas.

15. The imaging system of claim 14, the programmable optical switch network is configured to provide a first optical path from at least one light emitter to the selected transmit optical antenna and a second optical path from the selected receiving optical antenna to at least one light detector, wherein at least a portion of the first optical path is shared with the second optical path.

16. The imaging system of claim 14, wherein the selected transmit optical antenna and the selected receiving optical antenna are optically connected to at least one light emitter and at least one light detector via a single coupler.

17. The imaging system of claim 14, wherein the selected transmit optical antenna comprises the selected receiving optical antenna.

18. The imaging system of claim 14, wherein the selected transmit optical antenna and the selected receiving optical antenna transmit and receive light via a single microlens of the microlens array.

19. An integrated circuit for an imaging system, comprising:
an antenna array comprising a plurality of optical antennas; and
a microlens array comprising a plurality of microlenses corresponding to the plurality of optical antennas of the antenna array,
wherein the antenna array is positioned substantially at a focal plane of the microlens array, and
wherein centers of at least some of microlenses of the microlens array are offset relative to corresponding ones of optical antennas so as to redirect light from the corresponding ones of the optical antennas toward an aperture center of a lens of the imaging system.

20. The integrated circuit of claim 19, wherein the imaging system comprises an imaging LiDAR system, and wherein the plurality of optical antennas comprises transmit optical antennas and receiving optical antennas configured to transmit and receive light to and from a target via the lens and the microlens array.
